(19) United States
(12) Patent Application Publication
(10) Pub. No.: US 2013/0319528 A1
(43) Pub. Date: Dec. 5, 2013

(54) ORGANIC PHOTOVOLTAIC COATINGS WITH CONTROLLED MORPHOLOGY

(71) Applicants: Ling Qi, Orleans (FR); Bertrand Pavageau, Villenave D'Ornon (FR); Ashwin Rao, Norristown, PA (US)

(72) Inventors: Ling Qi, Orleans (FR); Bertrand Pavageau, Villenave D'Ornon (FR); Ashwin Rao, Norristown, PA (US)

(73) Assignee: RHODIA OPERATIONS, AUBERVILLIERS (FR)

(21) Appl. No.: 13/498,100

(22) PCT Filed: Sep. 24, 2010
(86) PCT No.: PCT/FR2010/052014

§ 371 Date: Jul. 8, 2013

(30) Foreign Application Priority Data
Sep. 25, 2009 (FR) 0956641

(51) Int. Cl. H01L 51/00

(52) U.S. Cl. CPC H01L 51/0007
USPC 136/263; 438/82

(57) ABSTRACT

The present invention relates to a method for producing a coating based on two organic semi-conducting compounds C_{P} and C_{N}, respectively of type P and of type N, C_{N} being immiscible with compound C_{P} in the coating produced, and wherein:
(A) a solution is deposited on the surface of the support, comprising compounds C_{P} and C_{N} in a solvent medium S capable of solvating compounds C_{P} and C_{N} without chemically reacting therewith, said solvent S being formed by a mixture of:
a first fraction formed by a solvent or a mixture of solvents S1 capable of solvating both compounds C_{P} or C_{N}; and
a second fraction miscible with the first fraction consisting of a solvent or a mixture of solvents S2 with a higher boiling point than that of the solvent or mixture of solvents S1 and which is capable of solvating one of the compounds C_{P} or C_{N} but not the other one; and
(B) the solvent S present in the thereby produced deposit is removed by evaporation.

The present invention relates to the field of photovoltaic devices, so-called third generation devices, which apply semi-conductors of organic nature.

Such devices (in particular photovoltaic cells), which, in order to provide a photovoltaic effect, apply organic semi-conductors (often designated by OSC for Organic Semi-Conductors), are of a recent design. These systems, which began to be developed during the 1990s, aims at substituting in the long term, first and second generation devices which apply inorganic semi-conductors.

In photovoltaic devices which apply OSCs, the photovoltaic effect is provided by applying together two distinct organic compounds, used in a mixture, i.e.:
a first organic compound having a semi-conducting nature of the P type (electron donor), which is generally a compound, preferably a polymer which has electrons engaged in pi bonds, advantageously delocalized, and which is most often a conjugate polymer, typically poly(3-hexylthiophene), a so-called P3HT; and
a second organic compound which is immiscible with the first compound under the conditions of use of the photovoltaic device, and which has a semi-conducting nature of the N type (electron acceptor), this second compound most often being a derivative of fullerene, such as for example MPCB (methyl [6,6]-phenyl-C₆₁-butyrate).

The photovoltaic effect is obtained by placing both organic semi-conductors between two electrodes, in the form of a layer comprising both of these semi-conductors as a mixture (this layer being in direct contact with both electrodes, or optionally connected to at least one of the electrodes via an additional layer, for example a charge-connecting layer); and by irradiating the thereby produced photovoltaic cell with adequate electromagnetic radiation, typically with light from the solar spectrum. To do this, one of the electrodes is generally transparent to the electromagnetic radiation used: in a way known per se, a transparent ITO (indium oxide doped with tin) anode may notably be used. The layer based on the mixture of two semi-conductor organic compounds between the electrodes is typically obtained by depositing a solution of both compounds in a suitable solvent (ortho-xylene, for example in the case of a P3HT/MPCB mixture) and then by evaporating this solvent.

Under the effect of irradiation, the electrons of the organic semi-conductor of type P are energized, typically according to a so-called π-π* transition mechanism (passing from the highest occupied molecular orbital (HOMO) to the lowest unoccupied molecular orbital (LUMO)) this leads to an effect similar to the injection of an electron from the valence band into the conduction band in an inorganic semi-conductor, which leads to the generation of an exciton (electron/hole pair).

Because of the presence of the organic semi-conductor of type N in contact with the semi-conductor of type P, the thereby generated exciton may be dissociated at the P/N interface and the generated energized electron during the irradiation may thus be conveyed by the semi-conductor of type N towards the anode, the hole as for it being led towards the cathode via the semi-conductor of type P.

Photovoltaic devices applying organic semi-conductors are potentially promising. Indeed, considering the application of organic compounds of the polymer type as a replacement for inorganic semi-conductors, they provide the advantage of being more mechanically flexible and therefore less fragile, than the first and second generation systems. Moreover, they are more lightweight and further they are easier to make and prove to be less expensive.

However, to this day, photovoltaic devices using organic semi-conductors have low photovoltaic efficiencies, which is an obstacle to their actual use in the production of photovoltaic energy. Consequently, many efforts are made for trying to increase this efficiency.

Diverse solutions have been proposed for trying to improve the photovoltaic properties of photovoltaic devices using organic semi-conductors. Within this scope, it was notably proposed to add reactive additives to certain mixtures of organic semi-conductors. Within this scope, the addition of additives of the thiol type into mixtures of the P3HT/MPCB was notably proposed, for example in patent applications US2008/315187 or US2009/032808. The additives which were shown within this scope are however only adapted to mixtures of specific semi-conducting organic polymers, and this teaching cannot be transposed to other types of mixture. Further, the presence of reactive additives of the aforementioned type may prove to be detrimental in certain cases. In particular, a number of additives proposed within this scope are toxic or harmful for the environment, in particular when these additives have volatility inducing their release in the close environment of the photovoltaic cell. Moreover, the presence of these reactive additives may have in the more or less short term a negative influence on the mechanical and electrical properties of the layer ensuring the photovoltaic effect. In particular, it may induce the presence of non-conducting impurities or even affect the stability of the mixture of semi-conducting organic compounds (this is in particular the case of additives which may generate free radicals, such as thiols for example) which notably induces accelerated degradation of the semi-conducting compounds of type P such as P3HT.

An object of the present invention is to provide a more systematic method with which the photocatalytic efficiency of a mixture of P and N semi-conducting organic compounds may be improved, such as those applied in third generation photovoltaic devices, without having to introduce, in order to do this, reactive additives of the aforementioned type into the mixture of compounds used for obtaining the photovoltaic effect.

For this purpose, the present invention provides a novel technique for making layers based on a mixture of semi-conducting organic compounds respectively of the type P and of the type N, which allows optimization of the mixture of both compounds within the obtained layer, and this is found to ensure increased photovoltaic efficiency regardless of the relevant pair of semi-conductors.

More specifically, the object of the present invention is a method allowing application on all or part of the surface of a support of an organic coating of photovoltaic nature based on a mixture of organic semi-conductors which comprises at least one first semi-conducting organic compound C_{P}, of type P, and at least one second semi-conducting organic compound C_{N}, of type N, immiscible with the compound Cp in the obtained coating. This method for applying the coating comprises the following steps:
(A) a solution is deposited on all or part of the surface of the support, comprising the compound C_{P} and C_{N} in a solvent medium S capable of solvating the whole of the compound C_{P} and C_{N} without chemically reacting with the latter, said solvent S consisting of a mixture of:
   a first fraction consisting of a solvent or a mixture of solvents S1 having a lower boiling point than that of the compounds C_{P} and C_{N} and which is capable of solvating both compounds C_{P} or C_{N}; and
   a second fraction, miscible with the first fraction, consisting of a solvent or a mixture of solvents S2 which has a boiling point, higher than that of the solvent or mixture of solvents and lower than that of the compounds C_{P} and C_{N} and which is capable of selectively solvating one of the compounds C_{P} or C_{N} but not the other one (i.e. unable to solvate C_{N} or C_{P} respectively); and
(B) the solvent S present in the thereby produced deposit on the support is removed by evaporation.

In the method of the present invention, the mixture of organic semi-conducting compounds C_{P} and C_{N} is deposited in a solvated form, like in the deposits of such mixtures made in presently known methods, but with a fundamental difference, i.e. a very specific solvent is used formed by the mixture of the fractions S1 and S2 as defined above.

Considering the specificities of both of these fractions S1 and S2, during the step (B) for drying the solvent S, a very particular process operates which induces the formation of a specific morphology in the coating obtained in fine.

More specifically, during step (B), the fraction S1 more volatile than the fraction S2 evaporates first which leads to S2 phase enrichment in the solvent medium of the obtained deposit, which makes the solvent medium less and less capable of solvating the compound which the fraction S2 is able to solvate. The result is desolvatation of at least one portion of one of the compounds C_{P} or C_{N}, able to lead to a demixing phenomenon of this compound, the other compound (C_{N} or C_{P} respectively) on the other hand in a first phase remaining in a solvated form, considering the presence of a sufficient amount of fraction S1 in the medium, still having not evaporated. It is only in a second phase of step (B) that the totality of the solvents is evaporated, so as to leave as a coating a mixture of compounds C_{N} and C_{P} substantially solvent-free. Considering this desolvatation in two phases, of the compounds C_{N} and C_{P} and the immiscibility of the compounds C_{N} and C_{P}, the obtained solid coating on the support has a specific morphology having a high contact interface between the compounds C_{N} and C_{P}.

The method of the present invention inter alia has the advantage of leading to such properties being obtained without having to introduce into the coating any remaining additive in the final coating. The solvent S responsible for obtaining the structure is actually removed during step (B) of the method. It should be noted that an application of additives remaining in fine in the mixture of compounds C_{N} and C_{P}, is not excluded within the scope of the present invention but such additives do not prove to be necessary for obtaining the sought effect. According to a particularly interesting embodiment of the method of the invention, the steps (A) and (B) are conducted without applying in the solution of the compounds C_{N} and C_{P}, any additive which may chemically react with the compounds C_{P} and C_{N}. More generally, it is most often desirable that the solution comprising the compounds C_{P} and C_{N} which is applied in step (A) be excluded from compounds which may remain in the coating at the end of step (B), in particular compounds having a boiling point higher or equal to that of the compounds C_{N} and C_{P}. According to a typical embodiment, the solution comprising the compounds C_{P} and C_{N} of step (A) is formed by the compounds C_{P} and C_{N} and the solvent S (resulting from the mixture of the S1 and S2 fractions), excluding any other compound.

Optionally, the method of the invention may comprise an additional heat treatment step (C) for the solid coating obtained at the end of step (B), a so-called annealing step, which generally allows inter alia consolidation or even still further optimization of the morphology of the coating from step (B). Such a step does not prove however to be required for obtaining an improvement in the properties as observed within the scope of the present invention. Consequently, according to a particular embodiment, the method of the invention may not include such an additional heat post treatment step (C) for the coating obtained at the end of step (B).

When it is applied, step (C) is preferably conducted by bringing the coating to a temperature from 70° C. to 200° C. (for example between 100 and 180° C., notably between 130 and 150° C.) generally for 1 to 30 minutes, typically for 5 to 15 minutes. If necessary, this step is advantageously conducted under a controlled atmosphere (notably nitrogen, argon), for example in the case when either one and/or both of the compounds C_{N} or C_{P} prove to be sensitive to oxidation, to atmospheric humidity or else to any other compound which may be present in the air (a sulfur-containing pollutant for example). More generally, it should be noted on this subject that it is generally advantageous to conduct the whole of the steps of the method of the invention under a controlled and/or reducing atmosphere when either one and/or both of the compounds C_{N} or C_{P} is a sensitive compound of this type, which is often the case considering the strongly pronounced donor and acceptor natures of these compounds.

The work carried out by the inventors within the scope of the present invention gave the possibility of showing that the obtained morphology by applying steps (A) and (B) allows improvement in the photovoltaic properties of the produced coating, as compared with the known methods of a type wherein both compounds are deposited in solution in a solvent medium capable of solvating both compounds, i.e. without the presence of a specific fraction S2 applied in the method of the invention, and this in a quite pronounced way when step (C) is applied.

In particular, it is found that the method of the invention leads to a significant improvement in the photovoltaic efficiency of the coating, which is notably reflected by an increase in the power conversion efficiency (PCE) as well as in the filling factor (FF, i.e. fill factor) of photovoltaic devices applying a photovoltaic coating as obtained according to the invention. The values of PCE and FF are characteristic quantities of photovoltaic devices which are commonly used and are notably defined in the article “Conjugated Polymer-Based Organic Solar Cells”. published in Chemical Reviews, 107, (4), pp. 1324-1338 (2007). As a reminder, they are measured by applying the photovoltaic device comprising the material to be tested as a photovoltaic diode. The value of PCE corresponds to the ratio of the maximum power delivered by the material over the power of the light flux illuminating it. The fill factor (between 0 and 1) as for it reflects the nature of the material which is more or less far from that of an ideal diode (a form factor of 1 corresponding to the case of an ideal diode).

Without intending to be bound by a particular theory, considering the results of the work conducted within the scope of the present invention, it seems possible to put forward that the particular method which is the object of the present invention, seems to lead to a structure being obtained which is particularly well adapted to efficient conversion of light radiations into electric energy by the combination of the semi-conducting compounds C_{N} and C_{P}. In all likelihood, the method of the invention gives the possibility of obtaining multiple intricated domains of compounds C_{N} and C_{P} these domains having dimensions of the order of at most a few tens of nanometer, which are able to induce both a large number of produced C_{N}/C_{P} interfaces (essential in organic photovoltaic materials in order to ensure a sufficiently strong chemical potential gradient for separating the electron/hole pairs generated by the photovoltaic effect, which are coupled much more strongly than in the case of inorganic semi-conductors) with a very short distance to be covered for the holes and electrons within the material (allowing the electron and the hole to be able to reach the anode and the cathode respectively without being trapped by the material).

The method of the present invention has the advantage of being able to be conducted with any pair of semi-conducting organic compounds C_{N} and C_{P} of type N and of type P respectively, and non-miscible with each other under the conditions for forming and using the photovoltaic coating.

Thus, it is notably possible to use as a semi-conducting organic compound C_{N}, any electron acceptor material known for having such properties, which may for example be selected from the following compounds:
derivatives of fullerenes, such as MPCB (methyl[6,6]-phenyl-C61-butyrate);
PCNEPV (poly[oxa-1,4-phenylene-(1-cyano-1,2-vinylene)-(2-methoxy-5-(3,7-dimethyl-octyloxy)-1,4-phenylene)-1,2-(2-cyanovinylene)-1,4-phenylene);
polymers of the polyfluorene type;
poly(styrene sulfonate) (PSS).

Derivatives of fullerenes, in particular MPCB (methyl[6,6]-phenyl-C61-butyrate) prove to be most particularly well adapted as a semi-conducting organic compound C_{N} according to the present invention.

As a semi-conducting organic compound C_{P,} it is possible to use within the scope of the present invention any material known for having a semi-conducting nature of type P. Advantageously the semi-conducting organic compound C_{P} is a conjugate organic polymer preferably selected from the following compounds:
derivatives of polythiophene such as P3HT (poly(3-hexylthiophene)
tetracene,
anthracene
polythiophenes
MDMO-PPV (poly[2-methoxy-5-(3,7-dimethyloctyloxy)-1,4-phenylene-vinylene])
MEH-PPV (poly[2-methoxy-5-(2-ethyl-hexyloxy)-1,4-phenylene-vinylene])

Derivatives of polythiophene such as P3HT (poly(3-hexylthiophene) are particularly adapted as a semi-conducting organic compound C_{P} in the method of the present invention.

The organic semi-conducting compounds (C_{N} and C_{P}) which are used within the scope of the present invention may also be selected from conjugate aromatic molecules containing at least three aromatic rings, optionally fused rings. Organic semi-conducting compounds of this type may for example comprise 5, 6 or 7 conjugate aromatic rings, preferably 5 or 6. These compounds may be both monomers and oligomers or polymers.

The aromatic rings present on the organic semi-conductors of the aforementioned type may comprise one or more heteroatoms selected from Se, Te, P, Si, B, As, N, O or S, preferably from N, O or S. Moreover they may be bound through conjugate binding groups, such as the groups —C(T1)=C(T2)—, —C═C— —N(Rc)-, —N═N—, —N═C(R′)—, wherein T1 and T2 are for example independently, H, Cl, F, or a C₁—C₆ alkyl group (i.e. having from 1 to 6 carbon atoms), preferentially a C₄ alkyl group and Rc represents H, an optionally substituted alkyl or an optionally substituted aryl.

The aromatic rings may moreover be optionally substituted with one or more groups selected from alkyl, alkoxy, polyalkoxy, thioalkyl, acyl, aryl or substituted aryl, a halogen (in particular —F or Cl, preferably F), a cyano group, a nitro group and secondary or tertiary amines, optionally substituted, (preferably amines of formula —NRaRb wherein each of Ra and Rb is independently H, or an optionally substituted (and optionally fluorinated or perfluorinated) alkyl group, an optionally substituted (for example fluorinated) aryl group, alkoxy or polyalkoxy group.

More generally, organic semi-conducting compounds (C_{N} and C_{P}) which may be applied according to the present invention include compounds and polymers selected from conjugate hydrocarbon polymers and oligomers such as polyacenes, polyphenylenes, poly(phenylene vinylene)polyfluorene; fused aromatic hydrocarbons such as tetracene, chrysene, pentacene, pyrene, perylene, coronene, and more preferentially soluble derivatives of these compounds, such as p-substituted phenylenes, such as for example p-quaterphenyl (p-4P), p-quinquephenyl (p-5P), p-sexiphenyl (p-6P), or their substituted derivatives such as poly(3-substituted thiophene), poly(3,4-bisubstituted thiophene), polybenzothiophene, polyisothianaphthene, poly(λ-substituted pyrrole), poly(3-substituted pyrrole), poly(3-4-disubstituted pyrrole), polyfuranes, polypyridines, poly-1,3,4-oxadiazoles, polyisothianaphthenes, poly(1-substituted aniline), poly(2-substituted aniline), poly(3-substituted aniline), poly(2,3-disubstituted aniline), polyazulenes, polypyrene; compounds of pyrazoline, polyselenophenes; polybenzofuranes; polyindoles; polypyridazines; compounds of benzidine; compounds of stilbene; triazines; porphines, phthalocyanines, fluorophthalocyanins, naphthalocyanins or fluoronaphthalocyanins, optionally metallated; fullerenes and their derivatives, diphenoquinones; 1,3,4-oxadiazoles; 11,11,12,12-tetra-cyanonaphtho-2,6-quinodimethane; [alpha],[alpha]′-bis(dithieno[3,2-b2′,3′-d]-thiophene); substituted anthradithiophenes; 2,2′-bibenzo[1,2-b:4,5-b′]dithiophene.

The exact nature of the solvent S should be adapted depending on the nature of the semi-conducting compounds C_{N} and C_{P} applied in the method of the invention. Adapted solvents as fractions S1 and S2 for a pair of relevant compounds C_{N} and C_{P} may typically be selected by considering the Hansen parameters of both compounds C_{N} and C_{P} and by referring to Hansen's space. As a reminder, Hansen parameters (also called Hansen solubility parameters) of a given compound reflect its solvation and affinity properties towards other molecules. The Hansen parameters of a given chemical species are generally designated by δ_{D}, δ_{P}, δ_{H}, which respectively reflect dispersion energy, polar energy and hydrogen bond energy between these chemical species. These three parameters define the coordinates of a point in the three-dimensional Hansen space. The indexation of the chemical species in the Hansen space allows prediction of the affinity of two species, species generally being all the more compatible with each other since they are close to each other in the Hansen space. For more details concerning the Hansen parameters, the Hansen space and their uses for predicting affinities between molecules, reference may notably be made to “Solubility parameters”; Charles M. Hansen, Alan Beerbower, Kirk Othmer, supplement volume, pp. 889 to 890 2^{nd} Edition 1971.

In the Hansen space, for a given chemical species having solubility parameters δ_{D}, δ_{P} and δ_{H}, a solubility volume may be described, localized around the point of coordinates δ_{D}, δ_{P} and δ_{H}, which has typically the shape of a more or less deformed ellipsoid characterized in the three dimensions of the Hansen space by radii r_{D}, r_{P} and r_{H} respectively. This solubility domain allows the definition of solvents capable of solubilizing or solvating the relevant chemical species, these solvents being those for which the solubility volume covers at least partly the solubility volume of the chemical species.

Moreover it is possible to define for a chemical species e and for a solvent s a parameter designated by Σ(e, s) defined as follows:

Σ(e, s)=[(δ_{D(e)-}δ_{D(s)})/r_{D}]²+[(δ_{P(e)-}δ_{P(s)})/r_{P}]²+[(δ_{H(e)-}δ_{H(s)})/r_{H}]²−1.

wherein δ_{D(e)}, δ_{P(e)} and δ_{H(e)} are the three Hansen solubility parameters of species e;
r_{D}, r_{P} and r_{H} are the radii of the Hansen solubility space of species e in each of the three directions of the Hansen space; and
δ_{D(s)}, δ_{P(s)} and δ_{H(s)} are the Hansen solubility parameters of the solvent s.
   This parameter Σ(e, s) reflects the localization of the point of coordinates δ_{D(s)}, δ_{P(s)} and δ_{H(s)} representative of the solvent s in the Hansen space, with respect to the solubility volume of the species e, i.e.
Σ(e, s)<0: the point is inside the solubility volume;
Σ(e, s)>0: the point is outside the solubility volume.

Within the scope of the method of the present invention, the fraction S1 of the solvent S applied in the solution of step (A) may advantageously be selected from solvents for which the solubility volume partly intersects both the solubility volume of the compound C_{N} and the volume solubility of the compound C_{P}, as well as of the mixtures of such solvents.

As regards the fraction S2 of the solvent S, the latter may advantageously be formed by:
at least one solvent s for which Σ(C_{P}, s)<0 and Σ(C_{N}, s)>0 (solvent capable of selectively solvating C_{P} but not C_{N}) or a mixture of such solvents; or
at least one solvent s for which Σ(C_{P}, s)>0 and Σ(C_{N}, s)<0 (solvent capable of selectively solvating C_{N} but not C_{P}) or a mixture of such solvents.

Depending on the nature of the compounds C_{P} and C_{N}, the ratio of the fractions of solvents S1 and S2 to be applied, may vary to a quite wide extent. Generally, the fraction S2 is a minority within the solvent S, the volume ratio S2/(S1+S2) of the volumes of both fractions S1 and S2, measured before mixing (in order to get rid of possible contraction effects), being generally less than 50%, generally less than 25%, or even 10%. The observation of the improvement effect on the properties of the photovoltaic material according to the invention moreover does not require very high S2 fraction concentrations, substantial results being observed with values of the volume ratio S2/(S1+S2) as low as 0.001%. In order to obtain particularly interesting effects, it is generally of interest that this volume ratio S2/(S1+S2) be greater than or equal to 0.01%, more preferentially greater than or equal to 0.05%, and even more preferentially of at least 0.1%. Thus, typically, it proves to be interesting if the volume ratio S2/(S1+S2) is comprised between 0.05% and 10%, for example between 0.1% and 5%.

On the other hand, generally, regardless of the nature of the compounds C_{P} and C_{N}, the concentration of each of these compounds within the solvent S is advantageously comprised between 0.1% and 5% by mass based on the mass of the solution, preferably between 0.5% and 2%, before applying step (B), the thickness of the coating obtained at the end of step (B) being all the higher since this concentration is significant but also dependent on the method for applying the solution on the surface in step (A).

Moreover, the ratio of the amount of the compounds C_{P} and C_{N} is preferably such that the ratio of the total number of proton acceptor sites of the compound C_{P} over the total number of proton acceptor sites of the compound C_{N} is of the order of 1, for example between 0.8 and 1.2.

The method of the present invention, adapted to the application of a very large number of semi-conducting organic compounds of type N and P, inter alia finds an interesting application in the specific case when the semi-conducting organic compound C_{N} is a derivative of fullerene, in particular MPCB, where the semi-conducting organic compound C_{P} is a derivative of polythiophene, such as P3HT (poly(3-hexylthiophene).

In the following of the present description, for illustrative purposes, the invention will be described with reference to the specific case of the following pair of semi-conducting organic compounds:
C_{N=}MPCB (methyl[6,6]-phenyl-C₆₁-butyrate; and
C_{P=}P3HT (poly(3-hexylthiophene)),
   which corresponds to a pair of typical polymers within the scope of preparation of organic photovoltaic compositions.

However it should be well understood that mention of this specific pair is only made for illustrating the invention, which is not limited to the application of these sole compounds, but one of the forces of which on the contrary lies in the large modularity of the semi-conducting organic compounds, the application of which it allows.

In the particular case of the MPCB/P3HT pair, both compounds are preferably applied in step (A) with a mass ratio comprised between 0.2 and 5, and typically of the order of 1:1 in solvent S. The total concentration of MPCB/P3HT within the solution is preferably between 0.5 and 10%, for example of the order of 2% by mass based on the total mass of the composition S before applying step (B).

Moreover, in the particular case of the MPCB/P3HT pair, the solvent S applied in steps (A) and (B) of the method is advantageously a mixture of two fractions S1 and S2 selected as follows:
the fraction S1 applied in the case of the MPCB/P3HT pair may be selected from solvents generally recommended for producing the deposit of this mixture of polymers of this type, well known per se.

In particular, the fraction S1 may comprise one or more solvents selected from chlorobenzene, dichlorobenzene (o-dichlorobenzene, m-dichlorobenzene, p-dichlorobenzene), trichlorobenzene, benzene, toluene, chloroform, dichloromethane, dichloroethane, xylenes (in particular ortho-xylene), α,α,α-trichlorotoluene, methylnaphthalene (1-methylnaphthalene and/or 2-methylnaphthalene), chloronaphthalene (1-chloronaphthalene and/or 2-chloronaphthalene).

According to an interesting embodiment, the fraction S1 comprises at least one xylene, preferably at least one ortho-xylene. Preferably, the fraction S1 is entirely formed of one or more xylenes, for example ortho-xylene.
the fraction S2 applied in the case of the MPCB/P3HT pair advantageously comprises at least one solvent selected from one of the compounds fitting one of the general formulae (I), (II), (III) and (IV) below:

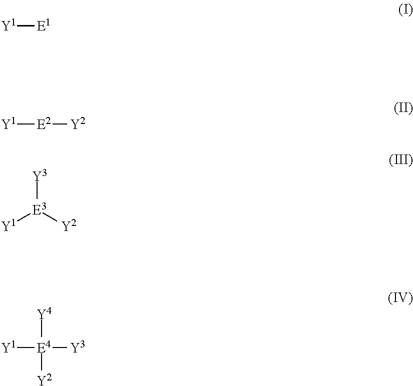

wherein:
each of the groups E¹, E², E³ and E⁴ is a saturated or unsaturated, linear or optionally branched, optionally aromatic, mono- di-, tri- and tetra-valent spacer hydrocarbon group respectively, and typically including from 1 to 20 carbon atoms, these spacer groups typically being groups of the alkyl, aryl, arylalkyl, or alkylaryl type (alkylene, arylene, arylalkylene, or alkylarylene for the polyvalent groups, respectively); and
each of the groups Y¹, Y², Y³ and Y⁴, either identical or different is a group bearing at least one polar function, optionally capable of producing intermolecular associations of the hydrogen bond or dipole-dipole type.

Preferably, each of the groups A, B, D and E is a bearer (of else is formed) of at least one amide, ester, ketone, carboxylic acid, aldehyde, amine, phosphonium, sulfonium or allylphosphonate group.

The fraction S2 applied in the case of the MPCB/P3HT pair is more preferentially formed of one or more solvents fitting one of the general formulae (I), (II), (III) and (IV).

More preferentially, the fraction S2 applied in the case of the MPCB/P3HT pair comprises (and preferably consists of) one or more of the solvents hereafter:
dicarboxylic acid diesters fitting the formula (II-1) below:

R¹−OOC-A-COO—R² (II-1)

wherein:
each of the groups R¹ and R², either identical or different, is cyclic or non-cyclic, linear or branched C₁-C₂₀ (i.e. including from 1 to 20 carbon atoms) alkyl, aryl, alkylaryl, or arylalkyl group; and
group A represents a linear or branched divalent alkylene group.

In these compounds of formula (II-1), the groups R¹ and R², either identical or different may notably be selected from methyl, ethyl, n-propyl, isopropyl, benzyl, phenyl, n-butyl, isobutyl, cyclohexyl, hexyl, n-hexyl, isooctyl, 2-ethylhexyl groups. The compounds of formula (II-1) are most particularly preferred, wherein R¹ and R² are 2-methyl, ethyl, or isobutyl,groups, preferably identical.

Group A of the compounds of formula (II-1) as for it is preferably a divalent C₁-C₆, preferably C₂-C₄ alkylene group.

The compounds of formula (II-1) may be described as the result of an esterification of a carboxylic diacid of formula HOOC-A-COOH with alcohols of formulae R¹—OH and R²—OH, either identical or different. According to a particular embodiment, the compounds of formula (I) may appear as a mixture of molecules which may be described as resulting from an esterification of a carboxylic diacid of formula HOOC-A-COOH with a mixture of alcohols, for example a mixture of natural alcohols, in particular, the alcohols present in triglycerides of natural oils (for example fusel oil).

When the group A is an ethylene group (—CH₂—CH₂—), a propylene group (—CH_{2—}CH_{2—}CH₂—) or butylene group (—CH₂—CH₂—CH₂—CH₂—), the compound of formula (II-1) is respectively a diester of the succinate diester, glutarate diester and adipate diester type.

According to an alternative of the invention, in the fraction S2, a mixture of several distinct dicarboxylic acid diesters of formula (II-1) is used. Alternatively, only one may be used.

According to a first embodiment, the group A of the compounds of formula (II-1) is a linear divalent group, notably an ethylene (—CH₂—CH₂—), propylene (—CH₂—CH₂—CH₂—) or butylene (—CH₂—CH₂—CH₂—CH₂—) group. Within this scope, compounds of formula (II-1) well adapted to the formation of the fraction S2 are dimethyl adipate, dimethyl glutarate and dimethyl succinate, preferably used as a mixture, preferably used as a mixture of these three compounds, advantageously with the following proportions for the 3 compounds (proportions given by mass), which may notably be determined by gas chromatography).
dimethyl adipate: from 9 to 17%;
dimethyl glutarate from 59 to 67% by weight,
dimethyl succinate from 20 to 28% by weight.

Another example of solvent according to this alternative are mixtures of the type of the solvent Rhodiasolv DEE marketed by Rhodia which comprises a mixture of compounds of formula (II-1) wherein A=ethylene (—CH₂—CH₂—), propylene (—CH₂—CH₂—CH₂—) and butylene (—CH₂—CH₂—CH₂—CH₂—) and wherein the R1 and R2 correspond to the chains of the alcohols present in fusel oil.

According to another embodiment, group A is a branched group, generally a branched divalent C₃-C₁₀ alkylene group.

The group A of the compounds of formula (II-1) may notably be a C₃ C₄, C₅, C₆, C₇, C₈, and C₉ group or else a mixture. Compounds of formula (II-1) wherein the group A is a C₄ group (i.e. comprising 4 carbon atoms) are particularly well adapted for forming a fraction S2 adapted to the case of the pair MPCB/P3HT. Within this scope the compounds of formula (II-1) are well adapted, wherein the group A is:
the group A_{MG} of formula —CH(CH₃)—CH₂—CH₂—, (corresponding to 2-methylglutaric acid); or
the group A_{ES} of formula —CH(C₂H₅)—CH₂—, (corresponding to 2-ethylsuccinic acid),
and mixtures of such compounds.

A particularly well adapted compound is the dimethyl ester of 2-methyl glutaric acid, fitting the following formula:

CH₃—OOC—CH(CH₃)—CH₂—CH₂—COO—CH₃,

used alone or in combination with other compounds.

According to a preferred embodiment, the applied fraction S2 in the case of the MPCB/P3HT pair comprises a mixture comprising the following dicarboxylic acid diesters:
a diester of formula R¹—OOC-A_{MG}-COO—R²
a diester of formula R¹—OOC-A_{ES}-COO—R²,
optionally an adipic diester of formula R¹—OOC—(CH₂)₄—COO—R²
   wherein: R¹ and R² preferably are methyl, ethyl or isobutyl groups.

This mixture preferably comprises:
from 70 to 95% by weight of the diester R¹—OOC-A_{MG}-COO—R², wherein R¹ and R² are preferably two methyl groups;
from 5 to 30% by weight of the diester R¹—OOC-A_{ES}-COO—R², wherein R¹ and R² are preferably two methyl groups;
optionally, up to 10% by weight of the diester R¹—OOC—(CH₂)₄—COO—R², preferably the methyl diester.

According to another embodiment, the fraction S2 contains diesters fitting the formula (nC₈H₁₈)—OOC—CHY—(CH₂)₂—COO-(nC₈H₁₈), wherein Y═H, CH₃ or C₂H₅. For example, it is possible to use a mixture of compounds of such compounds, wherein Y═CH₃ for 80 to 90% of the compounds and wherein Y═H for at least 5% of the compounds.
esteramides fitting the formula (II-2) below

R³OOC-A-CONR⁴R⁵ (II-2)

wherein:
R³ is a group selected from either saturated or unsaturated, linear or branched, optionally cyclic, optionally aromatic hydrocarbon groups comprising a number of carbon atoms ranging from 1 to 36,
R⁴ and R⁵, either identical or different are groups selected from either saturated or unsaturated, linear or branched, optionally cyclic, optionally aromatic, optionally substituted hydrocarbon groups comprising a number of carbon atoms ranging from 1 to 36, R² and R³ may optionally form together a ring, optionally substituted and/or optionally comprising a heteroatom and
A is a linear or branched divalent alkyl, preferably comprising an average number of carbon atoms ranging from 2 to 12, preferably from 2 to 4.

The groups R³, R⁴ and R⁵, either identical or different may notably be groups selected from C₁-C₁₂ alkyl, aryl, alkylaryl, arylalkyl groups or the phenyl group. The groups R² and R³ may optionally be substituted, notably with hydroxyl groups.

The group R³ may notably be selected from methyl, ethyl, propyl, isopropyl, n-butyl, isobutyl, n-pentyl, isopentyl, isoamyl, n-hexyl, cyclohexyl, 2-ethylbutyl, n-octyl, isoctyl, w-ethylhexyl, tridecyl groups.

The groups R⁴ and R⁵, either identical or different may notably be selected from methyl, ethyl, propyl, (n-propyl), isopropyl, n-butyl, isobutyl, n-pentyl, amyl, isoamyl, hexyl, cyclohexyl, hydroxyethyl groups. The groups R⁴ and R⁵ may also be such that they form together with the nitrogen atom a morpholine, piperazine or piperidine group. According to particular embodiments, R⁴═R⁵=methyl, or R⁴═R⁵=ethyl, or R⁴═R⁵=hydroxyethyl.

The group A present in the compounds of formula (II-2) may be a group A as defined within the scope of compounds (II-1).

According to a first particular embodiment, the group A of the compounds of formula (II-2) is a divalent linear alkyl group; typically —CH₂—CH₂— (ethylene); —CH₂—CH₂—CH₂— (n-propylene); or —CH₂—CH₂—CH₂—CH₂— (n-butylene). Within this scope, examples of compounds of formula (II-2) well adapted to the formation of the fraction S2 are the following compounds:
MeOOC—CH₂—CH₂—CONMe₂
MeOOC—CH₂—CH₂—CH₂—CONMe₂
MeOOC—CH₂—CH₂—CH₂—CONMe₂, mixed with
MeOOC—CH₂—CH₂—CH₂—CH₂—CONMe₂ and/or with MeOOC—CH₂—CH₂—CONMe₂.

According to a second embodiment, the group A of the compounds of formula (II-2) is a divalent branched alkylene group, preferably fitting one of the following formulas:
—(CHR⁷)_{y}—(CHR⁶)ₓ—(CHR⁷)_{z}—CH₂—CH₂—
—CH₂—CH₂—(CHR⁷)_{z}—(CHR⁶)ₓ—(CHR⁷)_{y}—
—(CHR⁷)_{z}—CH₂—(CHR⁶)ₓ—CH₂—(CHR⁷)_{y}—
—(CHR⁷)_{y}—(CHR⁶)ₓ—(CHR⁷)_{z}—CH₂—
—CH₂—(CHR⁷)_{z}—(CHR⁶)ₓ—(CHR⁷)_{y}—
   wherein:
x is an integer greater than 0,
y is an average integer greater than or equal to 0,
z is an average integer greater than or equal to 0,
each of the R⁶, either identical or different, is a C₁-C₆, preferably C₁-C₄ alkyl group, and
each of the R⁷, either identical or different, is a hydrogen atom or a C₁-C₆, preferably C₁-C₄ alkyl group.

In this second particular embodiment, the group A is preferably a group wherein y=z=0.

Other interesting groups A are:
the groups of formula —(CHR⁷)_{y}—(CHR⁶)ₓ—(CHR⁷)_{z}—CH₂—CH₂— or —CH₂—CH₂—(CHR⁷)_{z}—(CHR⁶)ₓ—(CHR⁷)_{y}— wherein −x=1; y=z=0; and R⁶=methyl.
the groups of formula —(CHR⁷)_{y}—(CHR⁶)ₓ—(CHR⁷)_{z}—CH₂— or —CH₂—(CHR⁷)_{z}—(CHR⁶)ₓ—(CHR⁷)_{y}— wherein −x=1; y=z=0; R⁶=ethyl.

Within this scope, examples of compounds of formula (II-2) well adapted to the formation of the S2 fraction are the following compounds:
MeOOC-A_{MG}-CONMe₂
MeOOC-A_{ES}-CONMe₂
PeOOC-A_{MG}-CONMe₂
PeOOC-A_{ES}-CONMe₂
CycloOOC-A_{MG}-CONMe₂,
CycloOOC-A_{ES}-CONMe₂
EhOOC-A_{MG}-CONMe₂
EhOOC-A_{ES}-CONMe₂
PeOOC-A_{MG}-CONEt₂
PeOOC-A_{ES}-CONEt₂
CycloOOC-A_{MG}-CONEt₂
CycloOC-A_{ES}-CONEt₂
BuOOC-A_{MG}-CONEt₂
BuOOC-A_{ES}-CONEt₂,
BuOOC-A_{MG}-CONMe₂,
BuOOC-A_{ES}-CONMe₂,
EtBuOOC-A_{MG}-CONMe₂,
EtBuOOC-A_{ES}-CONMe₂,
   wherein:
A_{MG} represents a —CH(CH₃)—CH₂—CH₂— group, or a —CH₂—CH₂—CH(CH₃)— group or a mixture of such groups
A_{ES} represents a —CH(C₂H₅)—CH₂— group, or —CH₂—CH(C₂H₅)— group or a mixture of such groups
Pe represents a pentyl group, preferably an isopentyl or isoamyl group,
Cyclo represents a cyclohexyl group,
Eh represents a 2-ethylhexyl group,
Bu represents a butyl group, preferably n-butyl or tertiobutyl,
EtBu represents an ethylbutyl group.

Potentially interesting compounds as solvents for the fraction S2 according to the invention are the compounds described in Examples 1.3 and 1.5 of the application WO2009/092795.
diamides fitting the formula (II-3) below:

R⁸R⁹NOC-A′-CONR¹⁰R¹¹ (II-3)

wherein:

each of R⁹, R¹⁰, R¹¹ and R¹², either identical or different, is:
a linear or branched, optionally totally or partly cyclized, preferably C₁-C₆, and more preferentially C₁-C₄ alkyl group; or
a phenyl group; and

A′ is a divalent group of formula —CH₂—CH₂—(CHR¹⁴)_{z}—(CHR¹³)ₓ—(CHR¹⁴)_{y}—
wherein:
x is an integer greater than 0,
y is an average integer greater than or equal to 0,
z is an average integer greater than or equal to 0,
each of the R¹³, either identical or different, is a C₁-C₆, preferably C₁-C₄ alkyl group, and
each of the R¹⁴, either identical or different, is a hydrogen atom or a C₁-C₆, preferably C₁-C₄ alkyl group.

The groups R⁸, R⁹, R¹⁰ and R¹¹, either identical or different, are preferably selected from methyl, ethyl, propyl, (n-propyl), isopropyl, n-butyl, isobutyl, n-pentyl, amyl, isoamyl, hexyl, cyclohexyl groups. They are preferably identical.

The groups R¹⁴ may notably be linear, branched or cyclic.

According to a particular embodiment, in the group A′, y=z=0.

The group A′ is preferably a group wherein x=1, −y=z=0, and −R⁶=methyl, which corresponds to the central group of 2-methylglutaric acid.

Moreover, it is preferable in the compounds of formula (II-3) that:
group A′ be such that:
   −x=1,
   −y=z=0,
   −R⁶=methyl, and
R², R³, R⁴ and R⁵ be identical and selected from methyl, ethyl, n-propyl, or isobutyl groups.

Examples of compounds of formula (II-3) adapted for making up the fraction S2 of the solvent applied within the scope of the present invention, are the compounds of the following formulae:

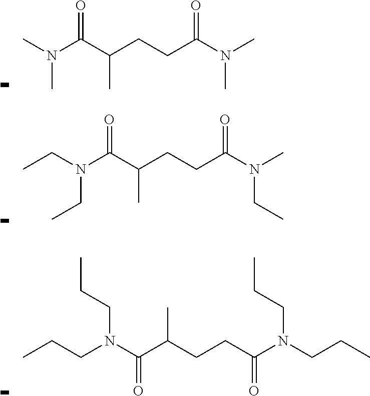

Another adapted compound of formula (II-3) is the compound fitting the following formula:

(phenyl)₂-NOC—CH₂—CH₂—CH(CH₃)—CON-(phenyl)₂.

The exemplified compounds in Examples 4 and 5 of WO 2008/074837 also prove to be adapted as solvents for making up the fraction S2 used within the scope of the present invention.
monoester compounds of formula (I-1) below:

A″-COO—R¹⁵ (I-1)

wherein:
the group R¹⁵ is a linear or branched, cyclic or non-cyclic, for example C₁-C₃₆ alkyl, aryl, alkylaryl, or arylalkyl group, for example a C₁-C₂₀ group (typically a methyl, ethyl or propyl group); and
the group A″ represents a linear or branched alkyl group preferably including from 2 to 6 carbon atoms, for example 4 carbon atoms.

A″ may notably be a linear ethyl, propyl or butyl group or else a branched group of formula —CH(CH₃)—CH₂—CH₃, or CH(C₂H₅)—CH_{3.}
monoamide compounds of formula (I-2) below

A′″-CONR¹⁶R¹⁷ (I-1)

wherein:
each of the groups R¹⁶ and R¹⁷, either identical or different, is a linear or branched, cyclic or non-cyclic C₁-C₃₆ for example C₁-C₂₀ alkyl, aryl, alkylaryl or arylalkyl group (typically a methyl, ethyl, or propyl group); and
the group A′″ represents a linear or branched alkyl group preferably including from 2 to 6 carbon atoms, for example 4 carbon atoms.
A′″ may notably be a linear ethyl, propyl or butyl group or else a branched group of formula —CH(CH₃)—CH₂—CH₃ or CH(C₂H₅)—CH_{3.}

According to a particularly well adapted embodiment, the fraction S2 applied in the case of the MPCB/P3HT pair is formed by a mixture comprising by weight based on the total weight of the mixture:
from 70 to 95% of CH₃—OOC-A_{MG}-COO—CH₃;
from 5 to 30% of CH₃—OOC-A_{ES}-COO—CH₃,
optionally up to 10% of diester H₃C—OOC—(CH2)₄—COO—CH₃.

Moreover it should be noted that considering its great modularity, the method of the invention opens the possibility of applying a wide panel of solvents in steps (A) and (B). With this possibility, in many cases, it is possible to avoid the application of solvents having negative repercussions on the environment by substituting them with more interesting solvents, for example stemming from biological materials or from biomass, or else with a low impact on the environment.

The fraction S2 applied in the case of the MPCB/P3HT pair may advantageously be formed by one or more solvents selected from the following commercial solvents: Rhodiasolv RPDE; Rhodiasolv Iris; Rhodiasolv DEE; Rhodiasolv ADMA 810.

In particular, advantageously, it is possible to use the solvent marketed by Rhodia as RHODIASOLV IRIS.

Regardless of the exact nature of the compounds C_{N} and C_{P} and of the solvents, the steps (A) and (B) of the method are preferably applied as follows.

In step (A), the deposition of the solution over all or part of the surface may be carried out according to any means known per se. An interesting method, which leads at the end of step (B) to a photovoltaic coating being obtained with controlled and homogeneous thickness, consists of carrying out the deposition of step (A) by centrifugal coating (also known as “spin coating”) i.e. by applying the solution containing C_{N} and C_{P} on the rotating support. Another possibility consists of producing the deposition by calibrated scraping of the solution at the surface of the coating, typically with a microcalibrated blade. With these techniques, coatings may typically be obtained with a thickness comprised between 50 and 300 nm, generally of the order of 100 to 200 nm at the end of step (B).

The temperature for applying step (A) is selected so as not to affect the stability of the present compounds and to maintain solubility of the compounds C_{N} and C_{P} within the solution S as well as the non-miscibility of these compounds C_{N} and C_{P}. For this purpose, the temperature for applying step (A) is preferably comprised between 5 and 150° C., most often between 10 and 70° C. It may also be conducted at room temperature. The preparation of the solution S used in step (A) may be conducted at a higher temperature than that of step (A), for example between 50 and 80° C. notably by allowing optimal solvation of the compounds C_{N} and C_{P}.

The step (B) for evaporating the solvent S may, as for it, be both conducted by letting the solvent evaporate by itself and by activating this evaporation, for example by heating the surface (at a temperature which is likely to neither effect the stability of the compounds C_{N} and C_{P}, nor their non-miscibility), and/or by placing the surface thereof provided with the deposit achieved in step (A), under negative pressure or under a carrier gas flow (N₂ stream for example) capable of carrying away the solvent S. In all the cases, an evaporation of the solvent is observed in two phases which leads to the texturation control effect according to the invention, considering the specificities of the solvents of the fractions S1 and S2.

According to another more specific aspect, the object of the present invention is supports provided with a coating of photovoltaic nature of the type obtained (i.e. obtained or which may be obtained) according to the method described above in the present description.

In particular, the object of the invention is the use of the method of the invention for making photovoltaic cells. Within this scope, the photovoltaic coating is generally deposited on an anode (generally an anode transparent to visible radiations, for example in ITO, advantageously an ITO layer deposited on a plastic material sheet). The anode may be coated beforehand with a layer of a conducting material. Next, the photovoltaic coating according to the invention is deposited (by applying steps (A) and (B), and preferably (C)) and then a cathode is deposited on the photovoltaic coating (for example in the form of a metal overlayer, for example an aluminium overlayer).

Different aspects and preferential features of the invention are illustrated in the application examples hereafter.

### EXAMPLE

### Photovoltaic Cells Comprising an Organic Photovoltaic Coating Based on a P3HT/MPCB Mixture

Organic photovoltaic cells were prepared by applying the method of the invention for making the organic layer having an organic nature. More specifically, these cells were prepared under the conditions described hereafter.

On a glass support (1 cm x 1cm plate) coated with a conducting layer of indium oxide doped with ITO tin (a commercial support provided with an ITO layer with a thickness of 100 nm), a layer of PEDOT:PSS layer (charge collecting layer) with a thickness of 40 nm was deposited (obtained by spin coating and then by sol/gel texturation).

On the thereby prepared support, a photovoltaic coating was made under the conditions of the present invention.

To do this, P3HT and MPCB were dissolved in otho-xylene so as to obtain a solution comprising 1% by mass of P3HT and 1% by mass of MPCB in ortho-xylene (ortho-xylene playing the role of the fraction S1). This solution was placed with stirring at 70° C. in order to obtain complete solvation of P3HT and of MPCB.

A solvent comprising by mass 89% of dimethyl methylglutarate, 9% of dimethyl 2-ethylsuccinate and 1% of dimethyl adipate, obtained according to the method described below, was then added to the thereby obtained solution as a fraction S2.
76.90 g of methanol and 43.26 g of a mixture M consisting of 86.9% by weight of methylglutaronitrile, 11.2% by weight of ethysuccinonitrile and 1.9% by weight of adiponitrile were loaded into a 500 ml glass reactor provided with an upflowing coolant, with a stirrer and heated by an oil bath.
The reaction medium was then cooled to 1° C. and then 84.22 g of 98 weight % sulfuric acid were added. The reaction medium was then refluxed and maintained under these conditions for 3 hours.
Next, after cooling to 60° C., 63 g of water were added. The thereby obtained reaction medium was maintained at 65° C. for 2 hours.
117 g of additional water were then added, whereby a biphasic reaction medium was obtained. After removing the excess methanol by evaporation, both phases were decanted. The recovered organic phase was washed a first time with an aqueous solution saturated with sodium chloride additived with ammonia in order to obtain a pH close to 7, and then a second time with an aqueous solution saturated with sodium chloride, and then distillation of the organic phase was carried out.

The solution comprising the P3HT/MPCB mixture in the thereby obtained mixture S1/S2 was deposited by spin coating, with a speed of rotation of the plate of 700 rpm for 1 minute at room temperature (25° C.).

After evaporation of the solvents, a photovoltaic coating was obtained with a control structure according to the invention, having a thickness of about 150 nm.

A fine aluminium layer (a thickness of the order of about 100 nm) was then deposited as a cathode on the thereby produced coating.

Three distinct photovoltaic cells of this type were made, which only differ by the value of the volume ratio x of the fractions, S2/(S1+S2), (measured before mixing) in the P3HT/MPCB solution, equal to 0.1%; 0.5%; and 1%, respectively. Three similar cells were prepared, in which the produced coating was subject to an additional annealing step bringing the coating obtained at the end of the evaporation of the solvents to 150° C. for 15 minutes. Finally, as a comparison, a control photovoltaic cell was made by carrying out the photovoltaic coating operation from the solution of P3HT/MPCB without ortho-xylene, without any addition of a solvent S2.

The electric properties obtained for each of the cells (power conversion efficiency PCE, and fill factor FF) are copied into the table below, whence it emerges that addition of the fraction S2 induces a highly significant improvement in the properties of the cell, and this whether annealing is applied or not.

TABLE
electric properties of the photovoltaic cells

| Volume | PCE | PCE | FF | FF |
|---|---|---|---|---|
| fraction | without | after | without | after |
| S2/(S1 + S2) | annealing | annealing | annealing | annealing |
| 0 (control) | 0.20 | 0.81 | 0.34 | 0.29 |
| 0.1 | 0.35 | 1.26 | 0.38 | 0.39 |
| 0.5 | 0.48 | 1.23 | 0.41 | 0.44 |
| 1 | 0.48 | 1.24 | 0.39 | 0.39 |

1. A method for applying on all or part of the surface of a support, an organic coating with a photovoltaic nature based on a mixture of organic semi-conductors, which comprise at least one first semi-conducting compound C_{P}, of type P, and at least one second semi-conducting organic compound C_{N}, of type N, immiscible with compound Cp in the produced coating, said method comprising the following steps:
(A) a solution comprising the compounds C_{P} and C_{N} in a solvent medium S capable of solvating the whole of the compounds C_{P} and C_{N} without chemically reacting with the latter is deposited on all or part of the surface of the support, said solvent S being formed by a mixture of:
a first fraction consisting of a solvent or a mixture of solvents S1 having a boiling point below that of the compounds C_{P} and C_{N} and which is capable of solvating both compounds C_{P} or C_{N}; and
a second fraction, miscible with the first fraction, consisting of a solvent or a mixture of solvents S2, which has a boiling point above that of the solvent or mixture of solvents S1 and below that of the compounds C_{P} and C_{N} and which is capable of selectively solvating one of the compounds C_{P} or C_{N} but not the other one (i.e. unable to solvate C_{N} or C_{P} respectively); and
(B) the solvent S present in the thereby produced deposit on the support is removed by evaporation.

2. The method according to claim 1, which further includes an additional heat treatment step (C) for the solid coating obtained at the end of step (B).

3. The method according to claim 1, which does not include any heat treatment step for the solid coating obtained at the end of step (B).

4. The method according to claim 1, wherein the concentration of each of the compounds C_{P} and C_{N} within the solvent S is comprised between 0.1% and 5% by mass based on the mass of the solution before application of step (B).

5. The method according to claim 1, wherein:
the semi-conducting organic compound C_{N} of type N is selected from derivatives of fullerenes, [methyl[6,6]-phenyl-C₆₁-butyrate (MPCB)]
the semi-conducting organic compound C_{P} of type P is selected from derivatives of polythiophene.

6. The method according to claim 5, wherein the fraction S1 of the solvent S comprises one or more solvents selected from chlorobenzene, dichlorobenzene, trichlorobenzene, benzene, toluene, chloroform, dichloromethane, dichloroethane, xylenes, α,α,α-trichlorotoluene, methylnaphthalene, chloronaphthalene.

7. The method according to claim 6, wherein the fraction S1 of the solvent S comprises at least one xylene.

8. The method according to claim 5, wherein the fraction S2 of the solvent S comprises at least one solvent selected from one of the compounds fitting one of the general formulae (I), (II), (III) and (IV) below: 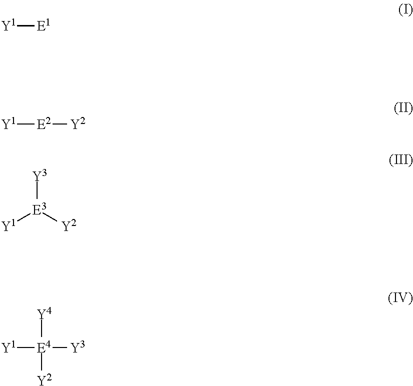
wherein:
each of the groups E¹, E², E³ and E⁴ is a saturated or unsaturated, linear or optionally branched mono-, di-, tri- and tetra-valent spacer hydrocarbon group, respectively, and including from 1 to 20 carbon atoms; and
each of the groups Y¹, Y², Y³ and Y⁴, either identical or different is a group bearing at least one polar function.

9. The method according to claim 5, wherein the fraction S2 comprises one or more of the solvents selected from:
dicarboxylic diesters fitting the formula (II-1) below:
R¹—OOC-A-COO—R² (II-1)
wherein:
each of the groups R¹ and R², either identical or different is a linear or branched, cyclic or non cyclic, C₁-C₂₀ alkyl, aryl, alkylaryl, or arylalkyl group; and
group A represents a linear or branched divalent alkylene group.
esteramides fitting the formula (II-2) below
R³OOC-A-CONR⁴R⁵ (II-2)
wherein:
R³ is a group selected from saturated or unsaturated, linear or branched, optionally hydrocarbon groups comprising a number of carbon atoms ranging from 1 to 36,
R⁴ and R⁵, either identical or different, are groups selected from saturated or unsaturated, linear or branched, substituted, hydrocarbon groups comprising a number of carbon atoms ranging from 1 to 36, R² and R³ may optionally form together a ring, and
A is a linear or branched divalent alkyl group,
diamides fitting the formula (II-3) below:
R⁸R⁹NOC-A′-CONR¹⁰R¹¹ (II-3)
wherein:
each of R⁹, R¹⁰, R11 and R¹², either identical or different, is
a linear or branched alkyl group; or
a phenyl group; and
A′ is a divalent group of formula —CH₂—CH₂—(CHR¹⁴)_{z}—(CHR¹³)ₓ—(CHR¹⁴)_{y}—
wherein:
x is an integer greater than 0,
y is an average integer greater than or equal to 0,
z is an average integer greater than or equal to 0,
each of the R¹³, either identical or different is a C₁-C₆ alkyl group; and
each of the R¹⁴, either identical or different, is a hydrogen atom or a C₁-C₆ preferably C₁-C₄ alkyl group,
monoester compounds of formula (I-1) below:
A″-COO—R¹⁵ (I-1)
wherein:
the group R¹⁵ is a linear or branched, cyclic or non-cyclic, C₁-C₃₆, alkyl, aryl, alkylaryl or arylalkyl group; and
the group A″ represents a linear or branched alkyl group,
monoamide compounds of formula (I-2) below
A′″-CONR¹⁶R¹⁷ (I-2)
wherein:
each of the groups R¹⁶ and R¹⁷, either identical or different is a linear or branched, cyclic or non-cyclic, C₁-C₃₆, alkyl, aryl, alkylaryl or arylalkyl group; and
the group A′″ represents a linear or branched alkyl group.

10. Supports provided with a coating having a photovoltaic nature which may be obtained according to the method of claim 1.

11. A photovoltaic cell comprising a layer having a photovoltaic nature which may be obtained as a coating according to the method of claim 1.

12. The method according to claim 5, wherein:
the semi-conducting organic compound C_{N} of type N is methyl[6,6]-phenyl-C₆₁-butyrate (MPCB).

13. The method according to claim 5, wherein:
the semi-conducting organic compound C_{P} of type P is poly(3-hexylthiophene) (P3HT).

14. The method according to claim 7, wherein the fraction S1 of the solvent S is ortho-xylene.
